(19) United States
(12) Patent Application Publication
(10) Pub. No.: US 2025/0391930 A1
(43) Pub. Date: Dec. 25, 2025

(54) PHYSICS-INFORMED STATE OF HEALTH FOR GRID APPLICATIONS USING A DIGITAL TWIN OF A BATTERY ENERGY STORAGE SYSTEM

(71) Applicant: Southwest Research Institute, San Antonio, TX (US)

(72) Inventors: Venkata Rajesh CHUNDRU, San Antonio, TX (US); Shreshta Rajakumar DESHPANDE, San Antonio, TX (US); Jayant Vitthal SARLASHKAR, San Antonio, TX (US); Stanislav A. GANKOV, San Antonio, TX (US); Scott R. HOTZ, Ann Arbor, MI (US)

(21) Appl. No.: 18/750,117

(22) Filed: Jun. 21, 2024

(51) Int. Cl. H01M 10/42; G01R 31/367; G01R 31/389; G01R 31/392; G05B 15/02; H01M 10/48; H02J 3/00; H02J 3/38; H02J 7/00

(52) U.S. Cl. CPC H01M 10/425; G01R 31/367; G01R 31/389; G01R 31/392; G05B 15/02; H01M 10/482; H02J 3/0012; H02J 3/38; H02J 7/00032; H02J 7/0016; H02J 7/0048; H02J 7/005; H01M 2010/4271; H01M 2010/4278; H01M 2220/10; H02J 2300/24; H02J 2300/28

(57) ABSTRACT

In an approach to a state of health for grid applications, a system includes one or more battery energy storage systems having a plurality of batteries; energy sources; power distribution systems; and computing devices. The computing devices are configured to: for each of the battery energy storage systems: receive battery parameters for each of the batteries from the battery energy storage systems; determine a lithium plating state, a solid electrolyte interface (SEI) thickness, and a dendrite length for each of the plurality of batteries; determine a battery state of health (SOH) for each of the batteries based on at least one of the lithium plating state, the SEI thickness, and the dendrite length; determine a battery charge profile to mitigate aging for each of batteries based on the SOH; and send updated battery parameters and control thresholds for each of batteries to each of the battery energy storage systems.

### FIELD

The present disclosure relates generally to renewable energy systems and, more particularly, to a system and method for physics-informed state of health for grid applications using a digital twin of a battery energy storage system (BESS).

### BACKGROUND

Battery storage is a technology that enables power system operators and utilities to store energy for later use. Battery storage is the fastest responding dispatchable source of power on electric grids, and it is used to stabilize those grids, as battery storage can transition from standby to full power in under a second to deal with grid contingencies. Battery energy storage systems (BESS) are devices that enable energy from renewables, like solar and wind, to be stored and then released when the power is needed most. Given that the supply of solar and wind power can fluctuate, battery energy storage systems are crucial to “smoothing out” this flow to provide a continual power flow. Intelligent battery software in the BESS uses algorithms to coordinate energy production and computerized control systems are used to decide when to store energy or to release it to the grid.

Energy storage based on lithium ion batteries is a critical piece of renewable energy source deployment in power grids. This system enables the storage of excess renewable energy and stabilize the power grid operation under high load conditions. The safety of these systems, particularly with respect to thermal runaway and overcharge leading to battery fires, is an important concern. One way to address this issue is to enforce dynamic power limits based on monitoring the internal states of the individual cells in terms of power (state of power-SOP) and aging (state of health-SOH). The aging states may consist of solid electrolyte interface (SEI), lithium plating, and dendritic growth.

A digital twin is a virtual hardware replica of an asset, such as a physical object or system, across its lifecycle. The digital twin is continuously updated with real-time data from the asset, and it uses the real-time data and other sources to enable learning, reasoning, and dynamically recalibrating for improved decision making. Simply, this means creating a highly complex virtual model that is the exact counterpart (or twin) of a physical thing. The ‘thing’ could be an automobile, a manufacturing process, a drug behavior, or even a smart city. Connected sensors on the physical asset collect data that can be mapped onto the virtual model. By viewing the digital twin, a user can see crucial information about how the physical thing is operating in the real world.

### BRIEF DESCRIPTION OF THE DRAWINGS

Reference should be made to the following detailed description which should be read in conjunction with the following figures, wherein like numerals represent like parts.

FIG. 1 is a functional block diagram illustrating a renewable energy distribution system incorporating physics-informed state of health for grid applications using a digital twin of a battery energy storage system consistent with the present disclosure.

FIG. 2 is a functional block diagram illustrating a battery energy storage system within the renewable energy distribution system of FIG. 1, consistent with the present disclosure.

FIG. 3 is a functional block diagram illustrating one or more energy sources within the renewable energy distribution system of FIG. 1, consistent with the present disclosure.

FIG. 4 is a functional block diagram illustrating a power distribution system within the renewable energy distribution system of FIG. 1, consistent with the present disclosure.

FIG. 5 illustrates plots of determined impedance (ZTR) versus cumulative charge, consistent with the present disclosure.

FIG. 6 illustrates an example system for monitoring battery performance and degradation consistent with the present disclosure.

FIG. 7 is a flowchart diagram depicting operations for monitoring battery performance and degradation according to one embodiment of the present disclosure.

FIG. 8 is a flowchart diagram depicting operations for monitoring battery performance and degradation according to one embodiment of the present disclosure.

FIG. 9 is a flowchart diagram depicting operations for grid applications using a digital twin of a battery energy storage system consistent with the present disclosure.

FIG. 10 depicts a block diagram of components of the computing device within the renewable energy distribution system of FIG. 1, consistent with the present disclosure.

### DETAILED DESCRIPTION

The present disclosure is not limited in its application to the details of construction and the arrangement of components set forth in the following description or illustrated in the drawings. The examples described herein may be capable of other embodiments and of being practiced or being carried out in various ways. Also, it may be appreciated that the phraseology and terminology used herein is for the purpose of description and should not be regarded as limiting as such may be understood by one of skill in the art. Throughout the present disclosure, like reference characters may indicate like structure throughout the several views, and such structure need not be separately discussed. Furthermore, any particular feature(s) of a particular exemplary embodiment may be equally applied to any other exemplary embodiment(s) of this disclosure as suitable. In other words, features between the various exemplary embodiments described herein are interchangeable, and not exclusive.

Battery energy storage systems connected to renewable energy systems, such as photovoltaic and wind power generation sources, are critical to grid decarbonization and grid stability. Disclosed herein is a system and method to estimate and control the health and safety of batteries in these systems under real-world grid duty cycle conditions. One of the critical states of interest for battery health management is monitoring the internal resistance of the cells and associated capacity and power fade. In this context, second life batteries are of particular interest, where safety is a primary concern. Second life batteries are batteries that can be applied for a different use after their initial lifecycle, e.g., in electric vehicles, is over. These batteries have reached the end of their “automotive” life but still have a residual capacity of about 70-80%, and reusing them in energy storage leads to economic and environmental benefits. This motivates precise modeling and control of the State of Health (SOH). To do so, a high-fidelity physics-based model is required. However, these models are computationally expensive to run on a real-time basis at the BESS site. An alternative is to run the models remotely at slower rates on computational platforms, such as cloud-based or mainframe servers, and extract the estimated SOH.

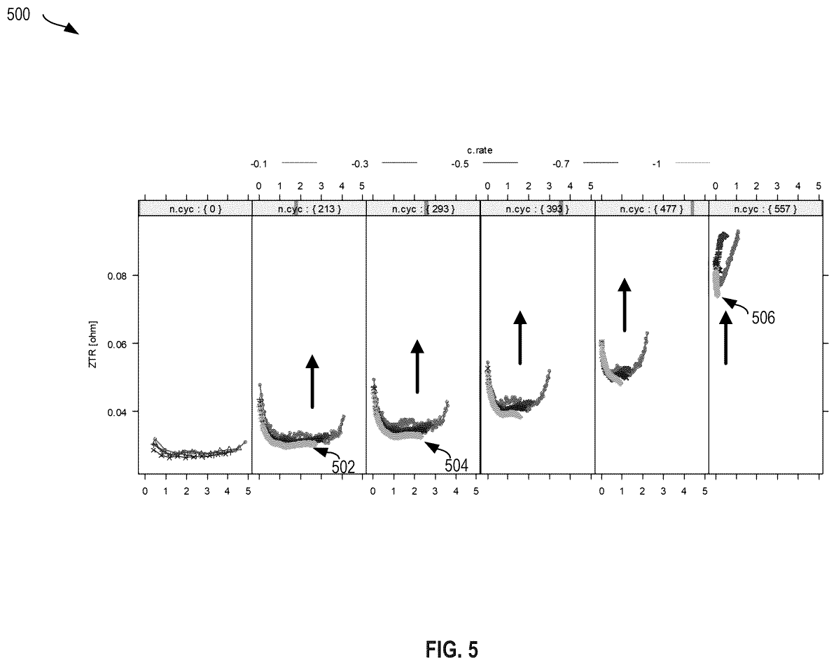

These physics-based models often require periodic feedback of the estimated state. In this context, a pseudo-electrochemical impedance spectroscopy (pseudo-EIS) may be leveraged to provide feedback from the BESS. The pseudo-EIS is further described in FIGS. 5-7 below. In the disclosed system, a digital twin of the BESS, which may include the pseudo-EIS, estimates the SOH of the batteries for real-time control of the BESS. The disclosed system imposes realistic dynamic power limits at a cell-level basis in the BESS. Further, the estimated SOH can be used to compute the residual value of the cell(s) for revenue generation calculations.

It should be noted that while lithium-ion batteries are discussed herein for clarity, other battery technologies, e.g., sodium ion cells, may be used and are fully supported by the system and method disclosed herein.

The industry standard model of a lithium-ion cell represents nominal physics through mass and charge conservation, and matching boundary conditions at the interface of electrodes and electrolyte. However, the standard model does not incorporate representation of ageing mechanisms. The pseudo-EIS test protocol subjects the battery in question to various levels of charging current with periodic interruption in charging. The system and methodology described herein includes behavioral representation of the ageing mechanisms (such as loss of cyclable lithium) and a real-time test protocol to keep the model true to reality and estimate degradation in performance and safety. The pseudo-EIS test protocol subjects the battery in question to various levels of charging current with periodic interruption in charging. Disclosed herein are a system and method to run these models offline in a digital twin in the cloud to realize cell- or module-level SOH estimation on a production BESS system.

In an embodiment, the disclosed implementation is cloud-based, and will perform SOH estimation while the energy management system (EMS) deployed on the BESS will leverage this information to enforce dynamic power limits on the BESS system. Part of the motivation to run the digital twin on the cloud is the scalability the cloud implementation offers for large BESS systems that might have hundreds or thousands of modules that need SOH monitoring. The cloud-based digital twin also allows for the storage of historical SOH data of these modules/cells for data analytics.

In an embodiment, the BESS primarily consists of lithium ion batteries with charge and discharge commands based on an EMS. As noted above, however, other battery technologies may be used and are fully supported by this disclosure. The EMS consists of a physics informed battery model which obtains its SOH estimates from the digital twin, which may use the pseudo-EIS as described in FIGS. 5-7 below. Dynamic power limits for charge and discharge are computed using the EMS and SOH states. The state of charge (SOC) of the battery is the amount of energy remaining in the battery, i.e., the ratio between the remaining energy in the battery and the maximum energy capacity of the battery while cycling. Typically, the SOC can only be estimated through other measurable parameters such as voltage, current, and temperature measurements, and the age of the battery.

In an embodiment, the battery management system (BMS) and EMS of a BESS compute the SOC and SOH using an equivalent circuit model (either at the cell-level or the rack-level). In the disclosed system, the parameters of this model and control thresholds for fast charge can be computed offline based on a digital twin. In an embodiment, the physics-based digital twin may estimate the lithium plating state, the solid electrolyte interface (SEI) thickness, and the dendrite length.

In another embodiment, the BESS, or possibly selective racks within the BESS, may enter a diagnostic mode wherein a pseudo-EIS is performed on the cell and/or racks. The resulting voltage and current measurements are transmitted to the digital twin and used as feedback mechanisms for the model-predicted states. In an embodiment, this process may be performed periodically; for example, every 100 cycles with a lower window size at lower SOH conditions. The digital twin leverages the experimental feedback and computes the charge profile to mitigate aging. This includes updated parameters and control thresholds provided to the EMS and BMS of the BESS.

Apart from controlling the charge profile, the model can also recommend changes to BESS thermal management strategies (where applicable). Further, the model outputs can be used for applications such as inventory management, forecasting capital expenditure and recommendations for BESS maintenance schedules.

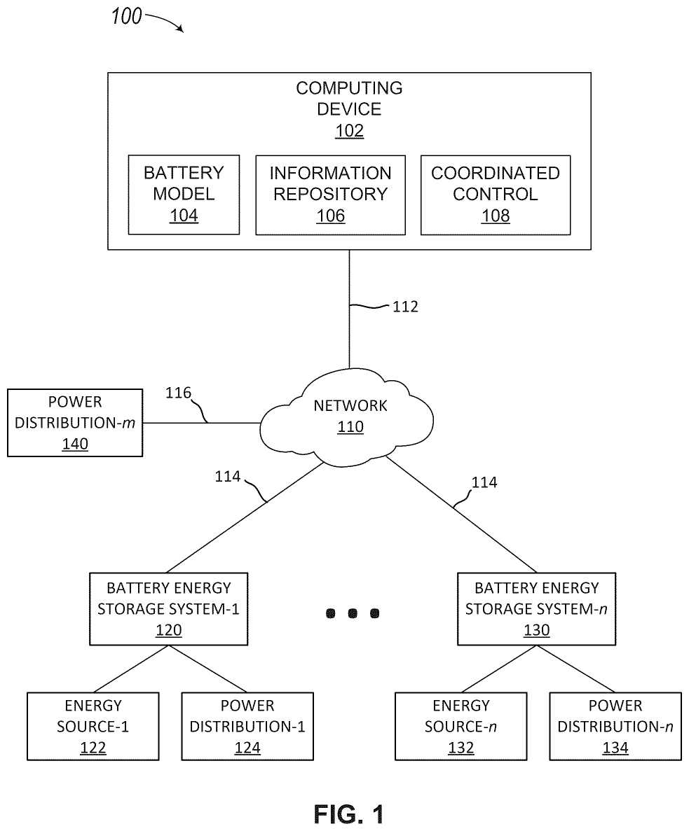

FIG. 1 is a functional block diagram illustrating a renewable energy distribution system 100 incorporating physics-informed state of health for grid applications using a digital twin of a battery energy storage system consistent with the present disclosure. FIG. 1 provides only an illustration of one implementation and does not imply any limitations with regard to the environments in which different embodiments may be implemented. Many modifications to the depicted environment may be made by those skilled in the art without departing from the scope of the disclosure as recited by the claims.

Renewable energy distribution system 100 includes computing device 102 optionally connected to network 110 through network connection 112. Network 110 can be, for example, a telecommunications network, a local area network (LAN), a wide area network (WAN), such as the Internet, or a combination of the three, and can include wired, wireless, or fiber optic connections. In general, network 110 can be any combination of connections and protocols that will support communications between computing device 102 and other computing devices (not shown) within renewable energy distribution system 100. In an embodiment, network 110 may be a cloud computing environment.

It should be understood that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. In an embodiment, this cloud model may include, but is not limited to, characteristics such as on demand self-service, broad network access, resource pooling, rapid elasticity, and measured service.

In an embodiment, this cloud model may include, but is not limited to, service models such as Software as a Service (SaaS), Platform as a Service (PaaS), and Infrastructure as a Service (IaaS). In an embodiment, this cloud model may include, but is not limited to, deployment models such as a private cloud, a community cloud, a public cloud, and/or a hybrid cloud (i.e., the cloud infrastructure is a composition of two or more clouds).

A cloud computing environment is service oriented with a focus on statelessness, low coupling, modularity, and semantic interoperability. At the heart of cloud computing is an infrastructure that includes a network of interconnected nodes.

In an embodiment, computing device 102 can be a laptop computer, a tablet computer, a netbook computer, a personal computer (PC), a desktop computer, or any programmable electronic device capable of receiving, sending, and processing data. In another embodiment, computing device 102 can represent a server computing system utilizing multiple computers as a server system, such as in a cloud computing environment. In yet another embodiment, computing device 102 represents a computing system utilizing clustered computers and components (e.g., database server computers, application server computers) that act as a single pool of seamless resources when accessed within renewable energy distribution system 100.

In an embodiment, computing device 102 includes information repository 106. Information repository 106 is a data repository that can store, gather, compare, and/or combine information. In some embodiments, information repository 106 is located externally to computing device 102 and accessed through a communication network, such as network 110. In some embodiments, information repository 106 is stored on computing device 102. In some embodiments, information repository 106 may reside on another computing device (not shown), provided that information repository 106 is accessible by computing device 102. Information repository 106 includes, but is not limited to, battery model data, battery health data, battery aging data, dynamic power limit data, digital twin data, inventory management data, capital expenditure data, maintenance data, and other data that is received by computing device 102 from one or more sources, and data that is created by computing device 102.

Information repository 106 may be implemented using any non-transitory volatile or non-volatile storage media for storing information, as known in the art. For example, information repository 106 may be implemented with random-access memory (RAM), solid-state drives (SSD), one or more independent hard disk drives, multiple hard disk drives in a redundant array of independent disks (RAID), optical library, or a tape library. Similarly, information repository 106 may be implemented with any suitable storage architecture known in the art, such as a relational database, an object-oriented database, or one or more tables.

In an embodiment, computing device 102 includes coordinated control 108. In an embodiment, the coordinated control 108 may contain an optimization algorithm to balance all connected BESS systems for SOC balancing as well as coordinated control of the discharge of connected BESS systems during a grid instability event.

In an embodiment, the optimization algorithm may balance the SOC of different BESS systems connected to the digital twin based on the health (i.e., SOH) of each BESS system. For example, if one BESS system has a higher SOC than the other BESS systems, then the optimization algorithm may choose the BESS system with the higher SOC to be the primary source of discharge. In this way, the optimization algorithm may equalize the BESS charge and discharge across the plurality of BESS systems connected to the digital twin.

In an embodiment, the optimization algorithm may control the discharge rate of all the connected BESS systems based on the individual BESS SOC, SOH and geographic location of the BESS system on the power grid in case of grid instability. In the event of grid instability, the system would normally select the BESS system closest to the instability to discharge to rectify the instability. If the SOC for the BESS system closest to the instability is low, then the optimization algorithm may select the BESS system closest to the instability that has a sufficient SOC.

Renewable energy distribution system 100 includes BESS-1 120 through BESS-n 130, coupled with computing device 102 through BESS network connections 114. It should be noted that although FIG. 1 shows two battery energy storage systems, any number of battery energy storage systems may be supported by renewable energy distribution system 100. Each BESS is connected to one or more energy sources and to a power distribution system. In the example of FIG. 1, BESS-1 120 is connected to energy source-1 122 and power distribution-1 124, while BESS-n 130 is connected to energy source-n 132 and power distribution-n 134. In an embodiment, the BESS network connections 114 may send battery parameters such as current, voltage, and temperature to the computing device 102, and may receive battery SOH information from computing device 102 via BESS network connections 114. It should be noted that in addition to the battery parameters and battery SOH information, any other data may be transferred to or from the BESS via BESS network connections 114.

Renewable energy distribution system 100 may include one or more power distribution-m 140, which may be similar to power distribution-1 124 through power distribution-n 134, but do not contain a BESS. In an embodiment, power distribution-m 140 may be connected to the network 110 via grid connection 116. The grid connections 116 may communicate, for example, grid conditions to the digital twin on the computing device 110. In an embodiment, these grid conditions may be used by the digital twin to establish a baseline condition of the grid which may be used to detect and locate any grid instabilities.

It should be noted that although the example of FIG. 1 shows computing device 102 connected to network 110, it is not so limited, and may be coupled with the BESS-1 120 through BESS-n 130 directly, or using any other method of coupling as would be known to one skilled in the art.

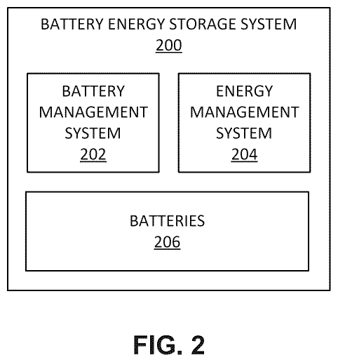

FIG. 2 is a functional block diagram illustrating a battery energy storage system 200, which may be, for example, BESS-1 120 or BESS-n 130 from FIG. 1, within the renewable energy distribution system 100 of FIG. 1, consistent with the present disclosure. BESS 200 includes battery management system BMS 202, energy management system EMS 204, and batteries 206. A battery management system such as BMS 202 is an electronic control unit that monitors and manages the performance of rechargeable batteries. It is a critical component of battery-powered systems. The primary function of the BMS 202 is to protect the battery from damage and failure. Lithium-ion batteries, for example, are prone to overcharging, over-discharging, and overheating. These conditions can cause permanent damage to the battery or even lead to fires or explosions. The BMS 202 continuously monitors the battery voltage, current, temperature, and other critical parameters to ensure that it operates within safe limits. It also provides real-time feedback to the EMS 204, ensuring the battery is charged and discharged correctly. In some embodiments, the BMS 202 may detect and isolate faulty cells or modules to prevent cascading failures.

Another critical function of a BMS is to optimize the battery's performance and lifespan. The BMS can balance the charge and discharge of individual cells or modules within the battery pack, ensuring they operate at similar levels. Cell balancing prevents overcharging or undercharging of individual cells, which can lead to capacity loss or reduced performance. The BMS can also provide accurate information about the battery's SOC. This information is essential for determining the battery's range, predicting its remaining lifespan, and optimizing its performance.

The energy management system, such as EMS 204, is the decision-making center of the BESS and is mainly responsible for real-time data collection, network monitoring, and energy scheduling. The EMS 204 efficiently coordinates the dispatch of battery stored energy to reduce the load on peak-generating sources by directing the BMS 202 to charge and store power during periods of excess generation and discharge or deliver the power during periods of excess demand. The EMS 204 contributes to grid stability by using battery storage for grid services such as frequency response and voltage regulation, and quickly responds to short-term imbalances in supply and demand using active (frequency) or reactive (voltage) control.

In an embodiment, the EMS 204 is directly responsible for the control strategy of the BESS, and the control strategy affects the decay rate and cycle life of the batteries in the system, thereby determining the economics of energy storage. In an embodiment, the EMS 204 also monitors fault abnormalities during system operation to provide timely and rapid notifications if faults are detected. The EMS 204 plays an important role in protecting equipment and ensuring safety.

In an embodiment, the EMS 204 works in conjunction with an optimization algorithm running on the digital twin in case of a grid instability event. For example, the EMS 204 may ensure that a higher discharge rate from a BESS system closer to the location of a fault does not propagate to the rest of the power grid.

In an embodiment, batteries 206 may be lithium-ion batteries, and may be, for example, second life batteries recovered from electric vehicles. While lithium-ion batteries are discussed herein, it should be noted that other battery technologies may be used and are fully supported by the system and method disclosed.

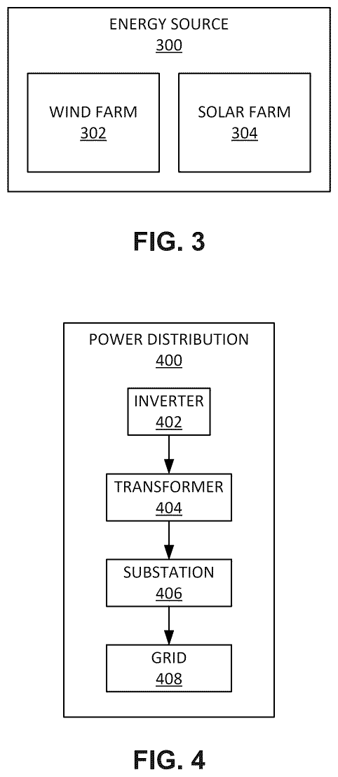

FIG. 3 is a functional block diagram illustrating one or more energy sources 300 within the renewable energy distribution system 100 of FIG. 1, consistent with the present disclosure. The energy sources 300 may include, but are not limited to, renewable energy generation systems including one or more wind power generation sources such as wind farm 302 and/or one or more photovoltaic sources such as solar farm 304.

FIG. 4 is a functional block diagram illustrating a power distribution system 400 within the renewable energy distribution system 100 of FIG. 1, consistent with the present disclosure. The power distribution system 400 includes inverter 402, which converts direct current (DC) electricity from the BESS to alternating current (AC) electricity for the grid. The AC current from the inverter 402 is then sent to one or more transformers 404, which change the voltage of the electrical signal coming out of the BESS, usually increasing (also known as “stepping up”) the voltage for transmission. The electrical current is then transmitted to a substation 406, where the electricity is converted into one or more lower voltages as needed. The electrical power is then distributed via grid 408. In some embodiments, the power distribution system 400 may be connected to the network 110 to communicate grid data to the digital twin. For example, the power distribution system 400 may be connected to the network 110 via the grid connections 116 to the substation 406. In an embodiment, the grid data may include, but is not limited to, data to locate fault events on the grid to provide support to the BESS to close the fault event.

FIG. 5 illustrates plots of determined impedance (ZTR) versus cumulative charge, which illustrates plots 500 of determined charge impedance (ZTR) versus cumulative charge for five (5) different normalized charging currents (−0.1, −0.3, −0.5, −0.7, and −1). For example, −1 and −0.1 correspond to 100% and 10%, respectively, of the rated charging current of the cell, where the minus sign indicates charging. As illustrated in FIG. 5, the impedance curves (groups) drift upward as the number of cycles (n_cyc) increases. This represents the overall degradation of the cell resulting from various internal mechanisms. The rightmost point of each curve, an example of which is shown at 502 for the normalized charging current of 1 at 213 charge/discharge cycles, corresponds to the charge capacity of the cell in A*hr. Note that, at a given level of the charge current, the rightmost point moves left as the number of cycles (n_cyc) increases—that is the capacity decreases, as illustrated by comparing endpoint 502 to 504. This is due to the constraint of the maximum allowable terminal voltage of the cell such that a charging controller (not shown) discontinues using the highest available charging current and must reduce charging current to ensure the terminal voltage of the cell does not exceed the maximum voltage constraint. In addition, the early termination of maximum charging current indicates an overall reduction in the inventory of cyclable lithium. As can be appreciated, the plots of FIG. 5 indicate that as a cell ages, the availability of the cell to use larger charging currents decreases, which in turn leads to an increase in charging time, and a decrease in overall charge capacity of the cell (in Ah). For a given cumulative charge [Ah], the charge resistance is lower at the higher level of current. This may be a result of alternative parallel paths that the current seeks—and lithium plating is a likely reason.

This observation of the nonlinearity of resistance with respect to charge current is an indication of loss of cyclable lithium and/or lithium plating and dendrite growth. The separation between the resistance at the lowest charging level (−0.1) and the highest charging level (−1) increases as lithium plating worsens. This is shown dramatically in the rightmost panel, in which the right endpoint 506 of the maximum charging current is significantly shortened and the overall charge capacity of the cell has decreased from approximately 5 Ah. to approximately 1 Ah. It is these observations that the present disclosure utilizes to develop charging (or discharging) thresholds that will cause a battery charging controller (not shown) to reduce charging current before these effects occur to extend the life of the cell and to prevent excessive lithium plating and dendrite growth, which can have significant fire and safety concerns.

The thresholds for the battery aging model are identified by analysis of Pseudo EIS tests. The thresholds are identified to target following aging mechanisms:
1. SEI growth rate (recoverable lithium)
2. Lithium plating state (irrecoverable lithium stored on anode surface)
3. Dendrite growth rate (once a dendrite growth rate has been predicted to exceed an experimentally-derived threshold, the battery should be taken out of service to prevent a fire hazard).

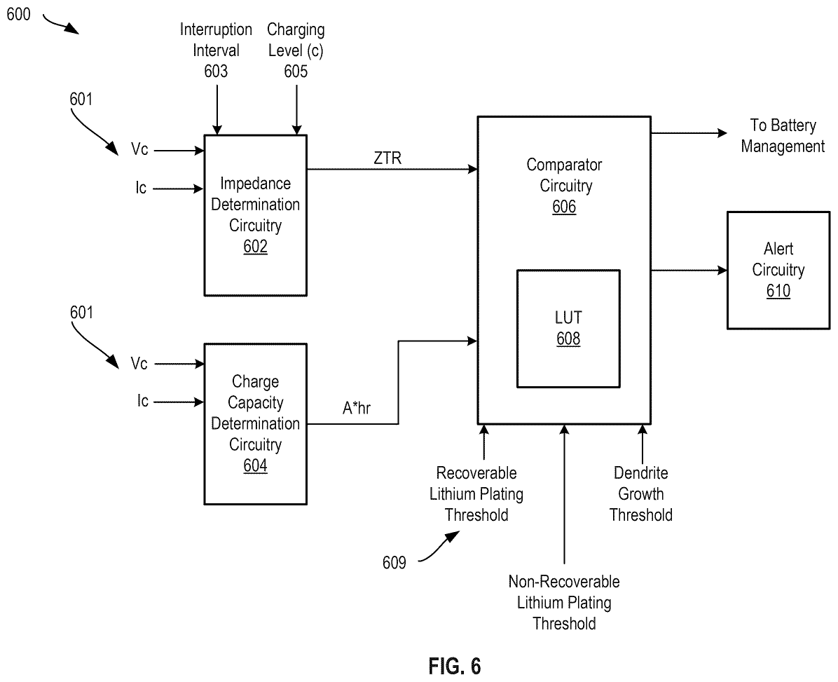

FIG. 6 illustrates an example system for monitoring battery performance and degradation consistent with the present disclosure. The system 600 of FIG. 6 may be incorporated with and/or formed as part of a battery management/charging system. As is known, a battery can be charged using a variety of charging levels. As the battery ages and in the presence of lithium plating, there tends to be a pronounced difference resistance between a low charging current value (e.g., 0.1 times the full charging current) and a high charging current value (e.g., the full charging current), and it is this difference in resistance (for a given battery age/cycle) that the digital twin in the present disclosure utilizes to determine thresholds for performance and safety characteristics. This difference becomes more pronounced as the battery ages, e.g., a new battery compared to an aged battery measured at 557 charge/discharge cycles. Accordingly, at selected cycle intervals (e.g., every 100 cycles, etc.), the impedance determination circuitry 602 is configured to make a plurality of resistance (ZTR) determinations through at selected charging/discharging cycles. To reveal a resistance separation between low charging current and high charging current, the impedance determination circuitry 602 may command a battery charging system to use a low battery charging current for a selected cycle, and on the next cycle or nearest next cycle, command the battery charging system to use a high charging current (or vise-versa). This will enable the impedance determination circuitry 602 to be able to generate resistance results for a battery having approximately the same age for low current resistance values and high current resistance values. For each charging current that is used by a battery charger, each of these resistance values may be stored, for example in a look-up table (LUT) 608.

The system 600 may also include charge capacity determination circuitry 604 to determine a battery charge capacity (A hr) based on the charging voltage (Vc) and charging current (Ic) values 601.

The system 600 also includes comparison circuitry 606 generally configured to compare the resistance values generated using a low charging current to corresponding resistance values generated using a high charging current. Thus, for example, if there are 100 interruption intervals during charging and thus 100 resistance measurements for each of the low charging current and high charging current, the comparison circuitry 606 is configured to compare the low charging current resistance values with the high charging current resistance values for each interval. Thus, low charging current resistance value 1 (at interval 1) is compared to high charging current resistance value 1 (at interval 1), low charging current resistance value 2 (at interval 2) is compared to high charging current resistance value 2 (at interval 2), and so on. The comparison circuitry 606 is also configured to determine a maximum difference between a low charging current resistance and a high charging current resistance among all of the intervals (hereinafter “maximum delta resistance”).

The comparison circuitry 606 is also configured to compare the maximum delta resistance to one or more thresholds 609 to determine degradation and or safety characteristics associated with the battery (i.e., battery aging characteristics). In this example embodiment, the comparison circuitry 606 is configured to compare the maximum delta resistance to a first threshold that represents a dendrite growth that has exceeded a preselected safety length (i.e., a dendrite growth threshold). As is known, dendrite growth can be a significant safety hazard, as dendrite growth can cause short circuiting and fire in a lithium-ion battery. If the maximum delta resistance value exceeds the dendrite growth threshold, the comparator circuitry 603 may trigger alert circuitry 610 (e.g., audible/visible alert), and may also cause battery management circuitry (not shown) to immediately cease any further charging or discharging of the battery. In this example embodiment, the comparison circuitry 606 is also configured to compare the maximum delta resistance to a second threshold that represents a non-recoverable lithium plating has occurred in the battery (i.e., a non-recoverable threshold). If the maximum delta resistance value exceeds the non-recoverable threshold (but remains below the dendrite growth threshold), the system 600 may generate an alert 610 (e.g., audible/visible alert), and may also cause the battery management circuitry to downwardly adjust the charging current to extend the life of the battery. For example, if the maximum delta resistance value exceeds the non-recoverable threshold, the maximum charging current may be reduced to, for example, 50% of maximum charging current. In this example embodiment, the comparison circuitry 606 is also configured to compare the maximum delta resistance to a third threshold that represents a recoverable lithium plating has occurred in the battery (i.e., a recoverable threshold). If the maximum delta resistance value exceeds the recoverable threshold (but remains below the non-recoverable and dendrite growth thresholds), the comparator circuitry 606 may generate an alert 610 (e.g., audible/visible alert), and may also cause the battery management circuitry to downwardly adjust the charging current to extend the life of the battery. For example, the charging current may be set to be 80% of maximum charging current.

In an embodiment, the alert circuitry 610 may update the digital twin with the SOC and SOH of any of the plurality of BESS systems based on the output of the comparison circuitry 606.

The thresholds 609 described above may be provided by the battery manufacturer/supplier and/or derived by experimentation for a given battery type and/or battery class using the pseudo-EIS protocol and determining resistance values. Such experimentation may include machine learning using a multi-nodal neural network processing architecture, for example, a multi-layer perception architecture, convolution neural network architecture, etc., to generate a model of behavioral characteristics of the battery. The term “machine learning” or “ML” refers to the use of computer systems implementing algorithms and/or statistical models to perform a specific task(s) without using explicit instructions but instead relying on patterns and inferences. ML algorithms build or estimate mathematical model(s) (referred to as “ML models” or the like) based on sample data (referred to as “training data,” “model training information,” or the like) to make predictions or decisions without being explicitly programmed to perform such tasks. Generally, an ML algorithm is a computer program that learns from experience with respect to some task and some performance measure, and an ML model may be any object or data structure created after an ML algorithm is trained with one or more training datasets. After training, an ML model may be used to make predictions on new datasets. Although the term “ML algorithm” refers to different concepts than the term “ML model,” these terms as discussed herein may be used interchangeably for the present disclosure. The term “machine learning model,” “ML model,” or the like may also refer to ML methods and concepts used by an ML-assisted solution. An “ML-assisted solution” is a solution that addresses a specific use case using ML algorithms during operation. ML models include supervised learning (e.g., linear regression, k-nearest neighbor (KNN), decision tree algorithms, support machine vectors, Bayesian algorithm, ensemble algorithms, etc.) unsupervised learning (e.g., K-means clustering, principle component analysis (PCA), etc.), reinforcement learning (e.g., Q-learning, multi-armed bandit learning, deep RL, etc.), neural networks, and the like. Depending on the implementation a specific ML model could have many sub-models as components and the ML model may train all sub-models together. Separately trained ML models can also be chained together in an ML pipeline during inference. An “ML pipeline” is a set of functionalities, functions, or functional entities specific for an ML-assisted solution; an ML pipeline may include one or several data sources in a data pipeline, a model training pipeline, a model evaluation pipeline, and an actor. The “actor” is an entity that hosts an ML assisted solution using the output of the ML model inference). The term “ML training host” refers to an entity, such as a network function, that hosts the training of the model. The term “ML inference host” refers to an entity, such as a network function, that hosts the model during inference mode (which includes both the model execution as well as any online learning if applicable). The ML-host informs the actor about the output of the ML algorithm, and the actor decides for an action (an “action” is performed by an actor as a result of the output of an ML assisted solution). The term “model inference information” refers to information used as an input to the ML model for determining inference(s); the data used to train an ML model and the data used to determine inferences may overlap, however, “training data” and “inference data” refer to different concepts.

The foregoing example embodiment is directed to determining ZTR based on charging current and voltage. In other embodiments, during charge operations, the battery may be controlled to perform a discharge operation during the interruption phase described herein. In such embodiment, ZTR (discharge) may be determined based on discharge current and voltage. ZTR (discharging), like ZTR (charging, described above), may provide insights into lithium plating and/or other battery degradation characteristics described herein.

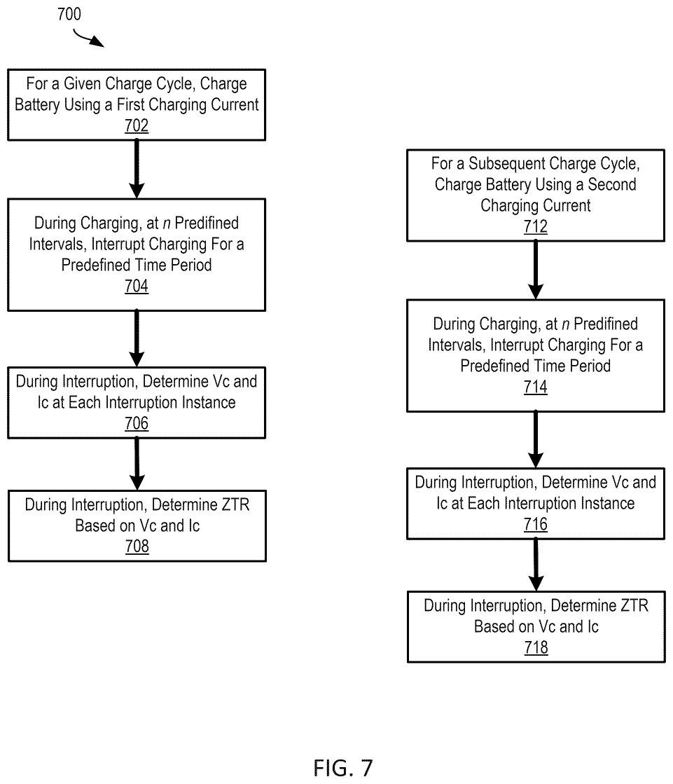

FIG. 7 is a flowchart diagram 700 depicting operations for monitoring battery performance and degradation according to one embodiment of the present disclosure. It should be appreciated that FIG. 7 provides only an illustration of one implementation and does not imply any limitations with regard to the environments in which different embodiments may be implemented. Many modifications to the depicted environment may be made by those skilled in the art without departing from the scope of the disclosure as recited by the claims.

Operations of this embodiment include, for a given charge cycle, charge a battery using a first charging current 702. Operations also include during charging at n predefined intervals, interrupt charging for a predefined time period 704. Operations also include during each interruption, determine a terminal voltage (Vc) and the charging current (Ic) 706. Operations also include during each interruption, determine a resistance value (ZTR) based on Vc and Ic 708. The collection of resistance values for the first charging current may be stored for later comparison. Operations of this embodiment also include, for a subsequent charge cycle, charge a battery using a second charging current 712. Operations also include during charging at n predefined intervals, interrupt charging for a predefined time period 714. Operations also include during each interruption, determine a terminal voltage (Vc) and the charging current (Ic) 716. Operations also include during each interruption, determine a resistance value (ZTR) based on Vc and Ic 718. The collection of resistance values for the second charging current may be stored for later comparison.

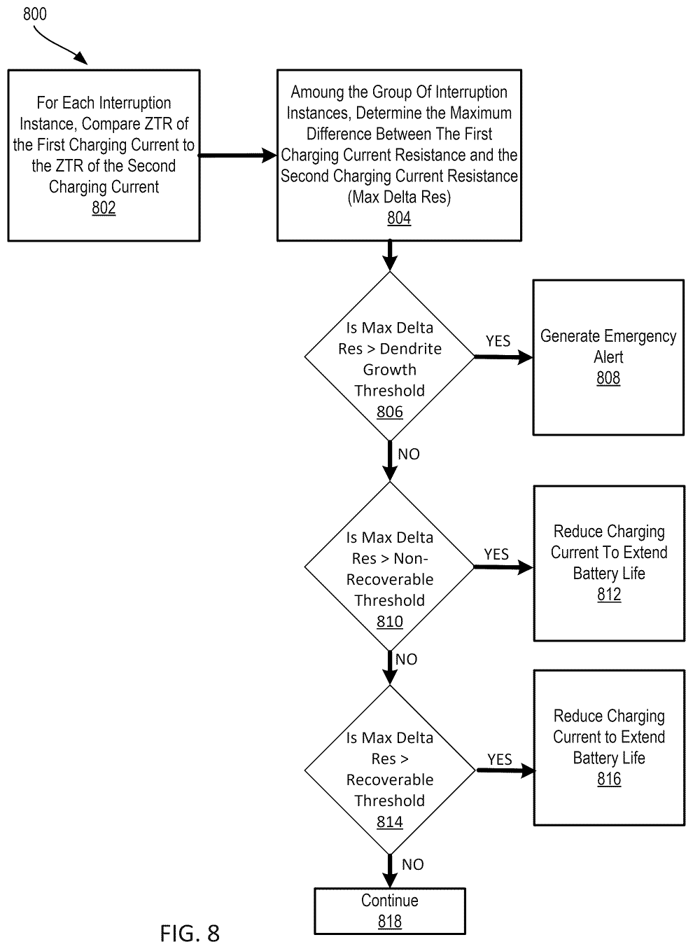

FIG. 8 is a flowchart diagram 800 depicting operations for monitoring battery performance and degradation according to one embodiment of the present disclosure. It should be appreciated that FIG. 8 provides only an illustration of one implementation and does not imply any limitations with regard to the environments in which different embodiments may be implemented. Many modifications to the depicted environment may be made by those skilled in the art without departing from the scope of the disclosure as recited by the claims.

Operations of this embodiment include, for each interruption instance, compare ZTR of the first charging current with ZTR of the second charging current 802. Operations of this embodiment also include, among the group of interruption instances, determine a maximum difference between the ZTR of the first charging current and ZTR of the second charging current (Max Delta Res) 804. Operations also include determining if Max Delta Res is greater than a dendrite growth threshold 806. If yes, operations include generating an emergency alert 808. If not, operations further include determining if Max Delta Res is greater than a non-recoverable (lithium) plating threshold 810. If yes, operations include reducing a charge current to extend battery life 812. If not, operations further include determining if Max Delta Res is greater than a recoverable (lithium) plating threshold 814. If yes, operations include reducing a charge current to extend battery life 816, otherwise continuing with charging operations 818.

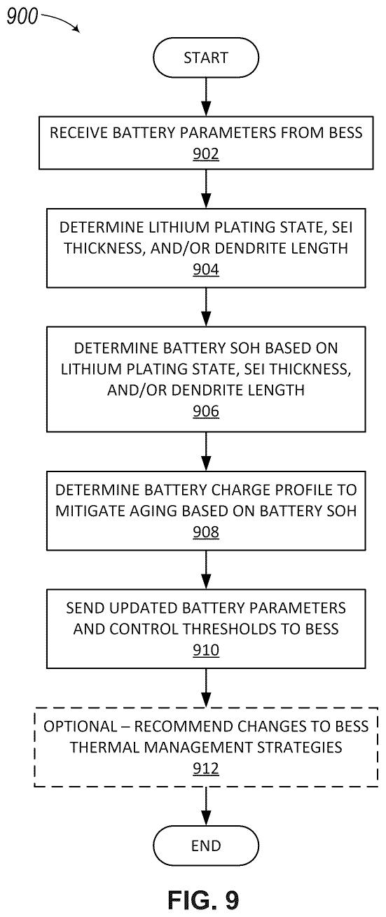

FIG. 9 is a flowchart diagram depicting operations for grid applications using a digital twin of a battery energy storage system consistent with the present disclosure. It should be appreciated that FIG. 9 provides only an illustration of one implementation and does not imply any limitations with regard to the environments in which different embodiments may be implemented. Many modifications to the depicted environment may be made by those skilled in the art without departing from the scope of the disclosure as recited by the claims.

Operations of this embodiment include receive battery parameters 902. In an embodiment, the battery parameters 902 may include, but are not limited to, current, voltage, and temperature. Operations also include determining the lithium plating state, the SEI thickness, and/or the dendrite length 904. Operations also include determining the battery SOH based on the lithium plating state, the SEI thickness, and/or the dendrite length 906. Operations also include determining the battery charge profile to mitigate aging based on the battery SOH 908. Operations of this embodiment also include sending updated battery parameters and control thresholds to the BESS 910. Operations of this embodiment may optionally include sending recommended changes to the BESS thermal management strategies 912. This optional step may include determining changes to thermal management strategies for each of the one or more battery energy storage systems based on the determined SOH for each of the plurality of batteries.

While FIGS. 7, 8 and 9 illustrate various operations according to one or more embodiments, it is to be understood that not all of the operations depicted in FIG. 7, 8 or 9 are necessary for other embodiments. Indeed, it is fully contemplated herein that in other embodiments of the present disclosure, the operations depicted in FIGS. 7, 8 and/or 9, and/or other operations described herein, may be combined in a manner not specifically shown in any of the drawings, but still fully consistent with the present disclosure. Thus, claims directed to features and/or operations that are not exactly shown in one drawing are deemed within the scope and content of the present disclosure.

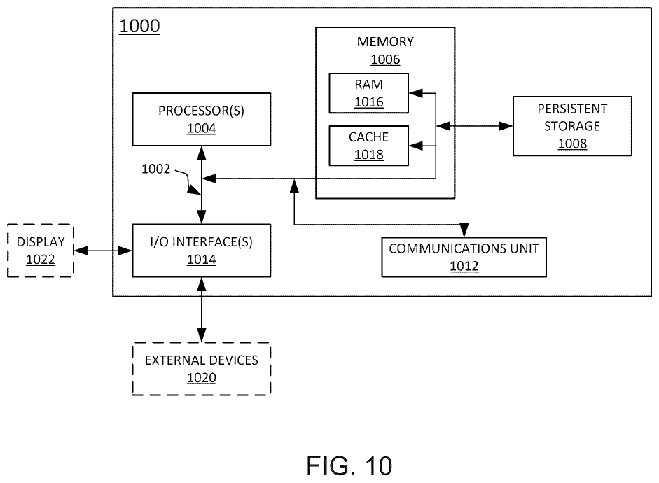

FIG. 10 is a block diagram depicting components of one example of the computing device 102 suitable for physics-informed state of health for grid applications using a digital twin of a battery energy storage system, within the renewable energy distribution system of FIG. 1, consistent with the present disclosure. FIG. 10 displays the computing device or computer 1000, one or more processor(s) 1004 (including one or more controllers or computer processors), a communications fabric 1002, a memory 1006 including, a random-access memory (RAM) 1016 and a cache 1018, a persistent storage 1008, a communications unit 1012, I/O interfaces 1014, a display 1022, and external devices 1020. It should be appreciated that FIG. 10 provides only an illustration of one embodiment and does not imply any limitations with regard to the environments in which different embodiments may be implemented. Many modifications to the depicted environment may be made.

As depicted, the computer 1000 operates over the communications fabric 1002, which provides communications between the computer processor(s) 1004, memory 1006, persistent storage 1008, communications unit 1012, and input/output (I/O) interface(s) 1014. The communications fabric 1002 may be implemented with an architecture suitable for passing data or control information between the processors 1004 (e.g., microprocessors, communications processors, and network processors), the memory 1006, the external devices 1020, and any other hardware components within a system. For example, the communications fabric 1002 may be implemented with one or more buses.

The memory 1006 and persistent storage 1008 are computer readable storage media. In the depicted embodiment, the memory 1006 comprises a RAM 1016 and a cache 1018. In general, the memory 1006 can include any suitable volatile or non-volatile computer readable storage media. Cache 1018 is a fast memory that enhances the performance of processor(s) 1004 by holding recently accessed data, and near recently accessed data, from RAM 1016.

Program instructions for physics-informed state of health for grid applications using a digital twin of a battery energy storage system may be stored in the persistent storage 1008, or more generally, any non-transitory computer readable storage media, for execution by one or more of the respective computer processors 1004 via one or more memories of the memory 1006. The persistent storage 1008 may be a magnetic hard disk drive, a solid-state disk drive, a semiconductor storage device, flash memory, read only memory (ROM), electronically erasable programmable read-only memory (EEPROM), or any other computer readable storage media that is capable of storing program instruction or digital information.

The media used by persistent storage 1008 may also be removable. For example, a removable hard drive may be used for persistent storage 1008. Other examples include optical and magnetic disks, thumb drives, and smart cards that are inserted into a drive for transfer onto another computer readable storage medium that is also part of persistent storage 1008.

The communications unit 1012, in these examples, provides for communications with other data processing systems or devices. In these examples, the communications unit 1012 includes one or more network interface cards. The communications unit 1012 may provide communications through the use of either or both physical and wireless communications links. In the context of some embodiments of the present disclosure, the source of the various input data may be physically remote to the computer 1000 such that the input data may be received, and the output similarly transmitted via the communications unit 1012.

The I/O interface(s) 1014 allows for input and output of data with other devices that may be connected to computer 1000. For example, the I/O interface(s) 1014 may provide a connection to external device(s) 1020 such as a keyboard, a keypad, a touch screen, a microphone, a digital camera, and/or some other suitable input device. External device(s) 1020 can also include portable computer readable storage media such as, for example, thumb drives, portable optical or magnetic disks, and memory cards. Software and data used to practice embodiments of the present disclosure can be stored on such portable computer readable storage media and can be loaded onto persistent storage 1008 via the I/O interface(s) 1014.

I/O interface(s) 1014 may also connect to a display 1022. Display 1022 provides a mechanism to display data to a user and may be, for example, a computer monitor. Display 1022 can also function as a touchscreen, such as a display of a tablet computer.

According to one aspect of the disclosure there is thus provided a system for state of health for grid applications, the system including one or more battery energy storage systems, each of the one or more battery energy storage systems having a plurality of batteries; one or more energy sources; one or more power distribution systems; and one or more computing devices. The one or more computing devices are configured to: for each of the one or more battery energy storage systems: receive battery parameters for each of the plurality of batteries from the one or more battery energy storage systems; determine a lithium plating state, a solid electrolyte interface (SEI) thickness, and a dendrite length for each of the plurality of batteries; determine a battery state of health (SOH) for each of the plurality of batteries based on at least one of the lithium plating state, the SEI thickness, and the dendrite length; determine a battery charge profile to mitigate aging for each of the plurality of batteries based on the SOH; and send updated battery parameters and control thresholds for each of the plurality of batteries to each of the one or more battery energy storage systems.

According to another aspect of the disclosure, there is provided a non-transitory storage device that includes machine-readable instructions that, when executed by one or more processors of a renewable energy distribution system, cause the one or more processors to perform operations. The operations include: receive battery parameters for each of a plurality of batteries from one or more battery energy storage systems; determine a lithium plating state, a solid electrolyte interface (SEI) thickness, and a dendrite length for each of the plurality of batteries; determine a battery state of health (SOH) for each of the plurality of batteries based on at least one of the lithium plating state, the SEI thickness, and the dendrite length; determine a battery charge profile for each of the plurality of batteries based on the SOH; and send updated battery parameters and control thresholds for each of the plurality of batteries to each of the one or more battery energy storage systems.

As used in this application and in the claims, a list of items joined by the term “and/or” can mean any combination of the listed items. For example, the phrase “A, B and/or C” can mean A; B; C; A and B; A and C; B and C; or A, B and C. As used in this application and in the claims, a list of items joined by the term “at least one of” can mean any combination of the listed terms. For example, the phrases “at least one of A, B or C” can mean A; B; C; A and B; A and C; B and C; or A, B and C.

“Circuitry,” as used in any embodiment herein, may comprise, for example, singly or in any combination, hardwired circuitry, programmable circuitry such as processors comprising one or more individual instruction processing cores, state machine circuitry, and/or firmware that stores instructions executed by programmable circuitry and/or future computing circuitry including, for example, massive parallelism, analog or quantum computing, hardware embodiments of accelerators such as neural net processors and non-silicon implementations of the above. The circuitry may, collectively or individually, be embodied as circuitry that forms part of a larger system, for example, an integrated circuit (IC), system on-chip (SoC), application-specific integrated circuit (ASIC), programmable logic devices (PLD), digital signal processors (DSP), field programmable gate array (FPGA), logic gates, registers, semiconductor device, chips, microchips, chip sets, etc.

The term “coupled” as used herein refers to any connection, coupling, link, or the like by which signals carried by one system element are imparted to the “coupled” element. Such “coupled” devices, or signals and devices, are not necessarily directly connected to one another and may be separated by intermediate components or devices that may manipulate or modify such signals.

Unless otherwise stated, use of the word “substantially” may be construed to include a precise relationship, condition, arrangement, orientation, and/or other characteristic, and deviations thereof as understood by one of ordinary skill in the art, to the extent that such deviations do not materially affect the disclosed methods and systems. Throughout the entirety of the present disclosure, use of the articles “a” and/or “an” and/or “the” to modify a noun may be understood to be used for convenience and to include one, or more than one, of the modified noun, unless otherwise specifically stated. The terms “comprising”, “including” and “having” are intended to be inclusive and mean that there may be additional elements other than the listed elements.

The programs described herein are identified based upon the application for which they are implemented in a specific embodiment of the disclosure. However, it should be appreciated that any particular program nomenclature herein is used merely for convenience, and thus the disclosure should not be limited to use solely in any specific application identified and/or implied by such nomenclature.

The present disclosure may be a system, a method, and/or a computer program product. The system or computer program product may include one or more non-transitory computer readable storage media having machine-readable instructions thereon for causing a processor to carry out aspects of the present disclosure.

The one or more non-transitory computer readable storage media can be any tangible device that can retain and store instructions for use by an instruction execution device. The one or more non-transitory computer readable storage media may be, for example, but is not limited to, an electronic storage device, a magnetic storage device, an optical storage device, an electromagnetic storage device, a semiconductor storage device, or any suitable combination of the foregoing. A non-transitory computer readable storage media, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from one or more non-transitory computer readable storage media or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in one or more non-transitory computer readable storage media within the respective computing/processing device.

The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some embodiments, electronic circuitry including, for example, programmable logic circuitry, Field-Programmable Gate Arrays (FPGA), or other Programmable Logic Devices (PLD) may execute the computer readable program instructions by utilizing state information of the computer readable program instructions to personalize the electronic circuitry, in order to perform aspects of the present disclosure.

It will be appreciated by those skilled in the art that any block diagrams herein represent conceptual views of illustrative circuitry embodying the principles of the disclosure. Similarly, it will be appreciated that any block diagrams, flow charts, flow diagrams, state transition diagrams, pseudocode, and the like represent various processes which may be substantially represented in computer readable medium and so executed by a computer or processor, whether or not such computer or processor is explicitly shown. Software modules, or simply modules which are implied to be software, may be represented herein as any combination of flowchart elements or other elements indicating performance of process steps and/or textual description. Such modules may be executed by hardware that is expressly or implicitly shown.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, a segment, or a portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the disclosure. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A system for state of health for grid applications, the system comprising:
one or more battery energy storage systems, each of the one or more battery energy storage systems having a plurality of batteries;
one or more energy sources;
one or more power distribution systems; and
one or more computing devices, the one or more computing devices configured to:
for each of the one or more battery energy storage systems:
receive battery parameters for each of the plurality of batteries from the one or more battery energy storage systems;
determine a lithium plating state, a solid electrolyte interface (SEI) thickness, and a dendrite length for each of the plurality of batteries;
determine a battery state of health (SOH) for each of the plurality of batteries based on at least one of the lithium plating state, the SEI thickness, and the dendrite length;
determine a battery charge profile to mitigate aging for each of the plurality of batteries based on the SOH; and
send updated battery parameters and control thresholds for each of the plurality of batteries to each of the one or more battery energy storage systems.

2. The system of claim 1, the one or more computing devices further configured to:
balance a state of charge (SOC) of each battery energy storage system of the one or more battery energy storage systems using an optimization algorithm based on the SOH of each battery energy storage system.

3. The system of claim 2, wherein balance the state of charge (SOC) of each battery energy storage system of the one or more battery energy storage systems using the optimization algorithm based on the SOH of each battery energy storage system further comprises:
responsive to detecting a grid instability, for each battery energy storage system of the one or more battery energy storage systems:
control a discharge rate of each battery energy storage system of the one or more battery energy storage systems based on at least one of the SOC, the SOH, and a geographic location of each battery energy storage system of the one or more battery energy storage systems.

4. The system of claim 1, wherein battery parameters for each of the plurality of batteries include at least one of current, voltage, and temperature.

5. The system of claim 1, wherein the plurality of batteries from the one or more battery energy storage systems are lithium ion batteries.

6. The system of claim 5, wherein any of the plurality of batteries from the one or more battery energy storage systems are second life batteries.

7. The system of claim 1, further comprising:
a digital twin of the one or more battery energy storage systems to determine the SOH for each of the plurality of batteries for each of the one or more battery energy storage systems.

8. The system of claim 7, wherein the digital twin further comprises a pseudo-electrochemical impedance spectroscopy (pseudo-EIS).

9. The system of claim 7, wherein the digital twin is cloud-based.

10. The system of claim 7, wherein the digital twin is used for at least one of inventory management, forecasting capital expenditure and recommendations for battery energy storage system maintenance schedules.

11. The system of claim 8, wherein determine the battery state of health (SOH) for each of the plurality of batteries based on at least one of the lithium plating state, the SEI thickness, and the dendrite length further comprises:
using the pseudo-EIS to determine the SOH for each of the plurality of batteries.

12. The system of claim 8, wherein determine the battery state of health (SOH) for each of the plurality of batteries based on at least one of the lithium plating state, the SEI thickness, and the dendrite length further comprises:
determine a first plurality of impedance values associated with a first charging current and a second plurality of impedance values associated with a second charging current; wherein each of the first and second plurality of impedance values being determined during a periodic interruption in charging; and
compare respective ones of the first plurality of impedance values to respective ones of the second plurality of impedance values, and to determine a maximum compared value representing a maximum difference between the first and second plurality of impedance values.

13. The system of claim 12, further comprising:
compare the maximum compared value to a first threshold representing a maximum dendrite growth length; and
responsive to the maximum compared value for any battery exceeds the first threshold, generate an alert.

14. The system of claim 12, further comprising:
compare the maximum compared value to a second threshold representing non-recoverable lithium plating within each of the plurality of batteries; and
responsive to the maximum compared value for any battery exceeds the second threshold, reduce a maximum charging current for the battery.

15. The system of claim 12, further comprising:
compare the maximum compared value to a third threshold representing recoverable lithium plating within each of the plurality of batteries; and
responsive to the maximum compared value for any battery exceeds the third threshold, reduce a maximum charging current for the battery.

16. The system of claim 1, further comprising:
determine recommended changes to thermal management strategies for each of the one or more battery energy storage systems based on the determined SOH for each of the plurality of batteries; and
send the recommended changes to each of the one or more battery energy storage systems.

17. A non-transitory storage device that includes machine-readable instructions that, when executed by one or more processors of a renewable energy distribution system, cause the one or more processors to perform operations, comprising:
receive battery parameters for each of a plurality of batteries from one or more battery energy storage systems;
determine a lithium plating state, a solid electrolyte interface (SEI) thickness, and a dendrite length for each of the plurality of batteries;
determine a battery state of health (SOH) for each of the plurality of batteries based on at least one of the lithium plating state, the SEI thickness, and the dendrite length;
determine a battery charge profile for each of the plurality of batteries based on the SOH; and
send updated battery parameters and control thresholds for each of the plurality of batteries to each of the one or more battery energy storage systems.

18. The non-transitory storage device of claim 17, wherein the instructions cause the one or more processors to further perform operations, comprising:
determine a first plurality of impedance values associated with a first charging current and a second plurality of impedance values associated with a second charging current; wherein each of the first and second plurality of impedance values being determined during a periodic interruption in charging; and
compare respective ones of the first plurality of impedance values to respective ones of the second plurality of impedance values, and to determine a maximum compared value representing a maximum difference between the first and second plurality of impedance values.

19. The non-transitory storage device of claim 18, wherein the instructions cause the one or more processors to further perform operations, comprising:
compare the maximum compared value to a first threshold representing a maximum dendrite growth length; and
responsive to the maximum compared value for any battery exceeds the first threshold, generate an alert.

20. The non-transitory storage device of claim 8, wherein the instructions cause the one or more processors to further perform operations, comprising:
compare the maximum compared value to a second threshold representing non-recoverable lithium plating within each of the plurality of batteries; and
responsive to the maximum compared value for any battery exceeds the second threshold, reduce a maximum charging current for the battery.

21. The non-transitory storage device of claim 8, wherein the instructions cause the one or more processors to further perform operations, comprising:
compare the maximum compared value to a third threshold representing recoverable lithium plating within each of the plurality of batteries; and
responsive to the maximum compared value for any battery exceeds the third threshold, reduce a maximum charging current for the battery.

22. The non-transitory storage device of claim 17, wherein the instructions cause the one or more processors to further perform operations, comprising:
determine recommended changes to thermal management strategies for each of the one or more battery energy storage systems based on the determined SOH for each of the plurality of batteries; and
send the recommended changes to each of the one or more battery energy storage systems.
